(19) United States
(12) Patent Application Publication
(10) Pub. No.: US 2016/0299185 A1
(43) Pub. Date: Oct. 13, 2016

(54) FAN DETECTING DEVICE AND FAN ASSEMBLY

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHANG-LONG PENG, Wuhan (CN); CHUN-SHENG CHEN, New Taipei (TW)

(21) Appl. No.: 14/721,701

(22) Filed: May 26, 2015

(30) Foreign Application Priority Data
Apr. 9, 2015 (CN) 201510163405.1

(51) Int. Cl. G01R 31/04

(52) U.S. Cl. CPC G01R 31/041

(57) ABSTRACT

A fan detecting device includes a motherboard, a first direct voltage, and an insert detecting unit. The motherboard includes a fan socket unit. The fan socket unit includes an insert detecting pin. The insert detecting unit includes a detecting terminal. The insert detecting pin is coupled to the first direct voltage and the detecting terminal. When the fan socket unit is void, the detecting terminal receives a high level signal. When the fan socket unit is coupled to a fan connector, the insert detecting pin is grounded; the detecting terminal receives a low level signal.

### CROSS-REFERENCE TO RELATED APPLICATIONS

This application claims priority to Chinese Patent Application No. 201510163405.1 filed on Apr. 9, 2015, the contents of which are incorporated by reference herein.

### FIELD

The subject matter herein generally relates to a fan detecting device and a fan assembly.

### BACKGROUND

A plurality of fans may be installed in a computer for dissipating heat from electrical components which generate heat. It is important to detect whether a fan is securely attached when the computer is working.

### BRIEF DESCRIPTION OF THE DRAWINGS

Implementations of the present technology will now be described, by way of example only, with reference to the attached figures.

FIG. 1 is a diagrammatic view of an embodiment of a fan assembly.

FIG. 2 is a circuit diagram view of the fan assembly of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

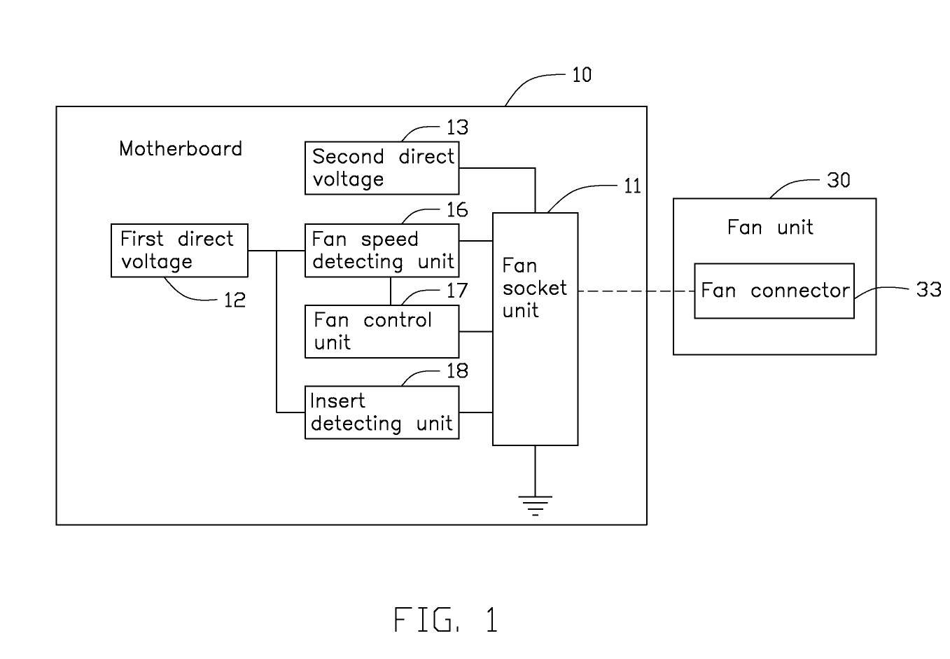

FIG. 1 illustrates a diagrammatic view of a fan assembly in one embodiment. The fan assembly can include a fan detecting device and a fan unit 30. The fan detecting device can include a motherboard 10. The fan detecting device can be used in an electronic device, such as a server, a laptop computer, a desktop computer, a tablet computer, an all-in-one computer, a smart TV, or a set top box.

The motherboard 10 includes a fan socket unit 11, a first direct voltage 12, a second direct voltage 13, a fan speed detecting unit 16, a fan control unit 17, and an insert detecting unit 18. The fan socket unit 11 is coupled to the second direct voltage 13, the fan speed detecting unit 16, the fan control unit 17, the insert detecting unit 18, and is grounded. The fan speed detecting unit 16 and the insert detecting unit 18 are coupled to the first direct voltage 12. The fan control unit 17 is coupled to the fan speed detecting unit 16.

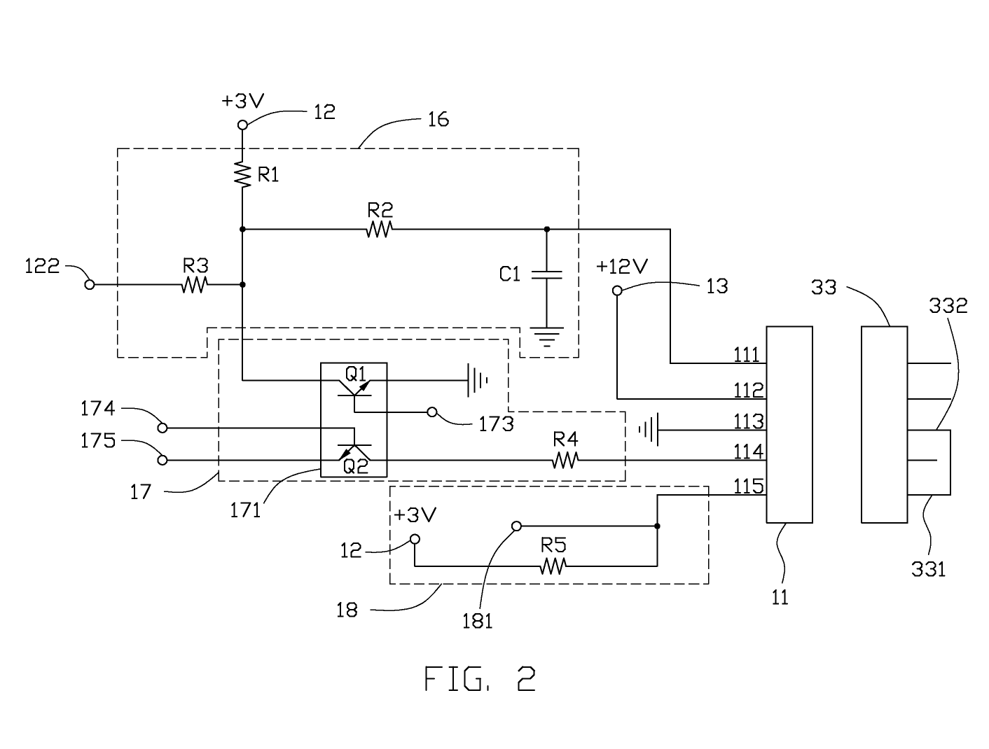

FIG. 2 illustrates a circuit diagram of the fan assembly. The fan unit 30 can include a fan connector 33. The fan connector 33 can include a first pin 331 and a second pin 332. The first pin 331 is coupled to the second pin 332.

The fan socket unit 11 can include a fan speed detecting pin 111, a power pin 112, a grounded pin 113, a fan control pin 114, and an insert detecting pin 115.

The fan speed detecting pin 111 is coupled to the fan speed detecting unit 16. The fan speed detecting pin 111 is coupled to the first direct voltage 12 through a first resistor R1 and a second resistor R2. The fan speed detected pin 111 is grounded through a capacitor C1. A signal receiving terminal 122 is coupled to the fan speed detecting pin 111 through the second resistor R2 and a third resistor R3 to receive a fan rotating speed signal from the fan unit.

The power pin 112 is coupled to the second direct voltage 13. The second direct voltage 13 can output about +12 volts.

The grounded pin 113 is grounded.

The fan control pin 114 is coupled to the fan control unit 17. The fan control unit 17 can include a switch 171. The switch 171 includes a first transistor Q1 and a second transistor Q2. A base of first transistor Q1 can be coupled to a first control terminal 173. A collector of the first transistor Q1 can be coupled to the fan speed detecting pin 111 through the second resistor R2. An emitter of the first transistor Q1 can be grounded. The first transistor Q1 can be an npn-type transistor. A base of second transistor Q2 can be coupled to a second control terminal 174. A collector of the second transistor Q2 can be coupled to the fan control pin 114 through a fourth resistor R4. An emitter of the second transistor Q2 can be coupled to a third control terminal 175. The second transistor Q2 can be an npn-type transistor. The first control terminal 173, the second control terminal 174, and the third control terminal 175 can be used to control the fan unit.

The insert detecting pin 115 is coupled to the insert detecting unit 18. As well the insert detecting pin 115 is coupled to the first direct voltage 12 through a fifth resistor R5. The first direct voltage 12 can output about +3 volts. A resistance of the fifth resistor R5 is about 8200 ohm. The insert detecting pin 115 is coupled to a detecting terminal 181. The detecting terminal 18 is coupled to a general purpose input/output (GPIO) port.

When the fan connector 33 is uncoupled from the fan socket unit 11, the insert detecting pin 115 is void; the detecting terminal 181 can receive a high level signal. The GPIO port can receive a signal that the fan unit is not coupled.

When the fan connector 33 is coupled to the fan socket unit 11, the first pin 331 is coupled to the insert detecting pin 115; the second pin 332 is coupled to the ground pin 113. The insert detecting pin 115 is grounded through the fan connector 33. The detecting terminal 181 receives a low level signal. The GPIO port can receive a signal that the fan unit is coupled to a computer.

A fan detecting device can detect whether a fan connector 33 is coupled to a fan socket unit 11 so that a computer system can alert when the fan connector 33 is uncoupled.

The embodiments shown and described above are only examples. Many details are often found in the art such as the other features of a fan detecting device and a fan assembly. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size and arrangement of the parts within the principles of the present disclosure up to, and including, the full extent established by the broad general meaning of the terms used in the claims. It will therefore be appreciated that the embodiments described above may be modified within the scope of the claims.

What is claimed is:

1. A fan detecting device comprising:
a motherboard comprising a fan socket unit, the fan socket unit comprising an insert detecting pin; and
a first direct voltage; and
an insert detecting unit comprising a detecting terminal, the insert detecting pin coupling to the first direct voltage and the detecting terminal,
wherein when the fan socket unit is void, the detecting terminal receives a high level signal, and when the fan socket unit is coupled to a fan connector, the insert detecting pin is grounded, the detecting terminal receives a low level signal.

2. The fan detecting device of claim 1, wherein the first direct voltage is about +3 volts.

3. The fan detecting device of claim 1, wherein the insert detecting pin is coupled to the first direct voltage through a first resistor.

4. The fan detecting device of claim 3, wherein a resistance of the resistor is about 8200 ohm.

5. The fan detecting device of claim 1, wherein the detecting terminal is coupled to a GPIO port.

6. The fan detecting device of claim 1, further comprising a second direct voltage, wherein the fan socket unit comprises a power pin, and the power pin is coupled to the second direct voltage.

7. The fan detecting device of claim 6, wherein the second direct voltage is about +12 volts.

8. The fan detecting device of claim 1, further comprises a fan control unit for controlling speed of the fan unit, wherein the fan control unit comprises a switch, the switch comprising two transistors.

9. The fan detecting device of claim 1, further comprises a fan speed detecting unit for receiving a rotating speed of the fan unit, wherein the fan speed detecting unit is coupled to the first direct voltage.

10. A fan assembly comprising:
a fan unit comprising a fan connector, the fan connector comprising a first pin and a second pin, and the first pin coupled to the second pin;
a motherboard comprising a fan socket unit, the fan socket unit comprising an insert detecting pin and a ground pin, the ground pin being grounded; and
a first direct voltage; and
an insert detecting unit comprising a detecting terminal, the insert detecting pin coupling to the first direct voltage and the detecting terminal,
wherein when the fan connector is uncoupled with the fan socket unit, the detecting terminal receives a high level signal, and when the fan connector is coupled to the fan socket unit, the first pin is coupled to the insert detecting pin, the second pin is coupled to the ground pin, the insert detecting pin is grounded, and the detecting terminal receives a low level signal.

11. The fan assembly of claim 10, wherein the first direct voltage is about +3 volts.

12. The fan assembly of claim 10, wherein the insert detecting pin is coupled to the first direct voltage through a first resistor.

13. The fan assembly of claim 12, wherein a resistance of the resistor is about 8200 ohm.

14. The fan assembly of claim 10, wherein the detecting terminal is coupled to a GPIO port.

15. The fan assembly of claim 10, further comprising a second direct voltage, wherein the fan socket unit comprises a power pin, and the power pin is coupled to the second direct voltage.

16. The fan assembly of claim 15, wherein the second direct voltage is about +12 volts.

17. The fan assembly of claim 10, further comprises a fan control unit for controlling speed of the fan unit, wherein the fan control unit comprises a switch, the switch comprising two transistors.

18. The fan assembly of claim 10, further comprises a fan speed detecting unit for receiving a rotating speed of the fan unit, wherein the fan speed detecting unit is coupled to the first direct voltage.

19. A fan assembly comprising:
a fan unit comprising a fan connector, the fan connector comprising a first pin and a second pin, and the first pin coupled to the second pin;
a motherboard comprising a fan socket unit, the fan socket unit comprising an insert detecting pin and a ground pin, the ground pin being connected to ground;
a first direct voltage; and
an insert detecting unit comprising a detecting terminal, the insert detecting pin coupling to the first direct voltage and the detecting terminal,
wherein when the fan connector is uncoupled with the fan socket unit, the detecting terminal receives a high level signal, and
wherein when the fan connector is coupled to the fan socket unit, the first pin is coupled to the insert detecting pin, the second pin is coupled to the ground pin, the insert detecting pin is grounded, and the detecting terminal receives a low level signal that represents that the fan connector is coupled to the fan socket unit.
